(19) United States
(12) Patent Application Publication
(10) Pub. No.: US 2008/0044951 A1
(43) Pub. Date: Feb. 21, 2008

(54) Semiconductor package and method of manufacturing the same

(75) Inventors: Hyo-jae Bang, Cheonan-si (KR); Dong-chun Lee, Cheonan-si (KR); Seong-chan Han, Cheonan-si (KR); Chang-yong Park, Cheonan-si (KR); Hun Han, Cheonan-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/812,145

(22) Filed: Jun. 15, 2007

(30) Foreign Application Priority Data
Aug. 17, 2006 (KR) 10-2006-0077810

(51) Int. Cl. H01L 23/52; H01L 21/00

(52) U.S. Cl. 438/121; 257/737; 257/E23.141; 257/E21.001

(57) ABSTRACT

A semiconductor package may include a substrate having external contact terminals. A semiconductor chip having bonding pads may be formed on the substrate. Conductive bumps may connect the external contact terminals of the substrate to the bonding pads of the semiconductor chip. An underfill may be interposed between the substrate and the semiconductor chip. The underfill may include a first underfill region composed of a first material adjacent to the semiconductor chip and a second underfill region composed of a second material adjacent to the substrate, the first material having a higher glass transition temperature than the second material.

### PRIORITY STATEMENT

This U.S. non-provisional application claims the benefit of priority to Korean Patent Application No. 10-2006-0077810, filed on Aug. 17, 2006, in the Korean Intellectual Property Office (KIPO), the disclosure of which is incorporated herein in its entirety by reference.

### BACKGROUND

1. Field

Example embodiments relate to a semiconductor package and method of manufacturing the same, for example, to a semiconductor package with heterogeneous underfill and method of manufacturing the same.

2. Description of the Related Art

In semiconductor packages, for example, memory devices, intervals between connection terminals are reduced to accommodate trends toward higher-speed and higher-integration, and thus higher packaging precision is required. The reduced interval between the connection terminals may cause defects due to a difference in coefficient of thermal expansion (CTE) between a semiconductor chip and a substrate.

FIG. 1A is a cross-sectional view illustrating a conventional semiconductor package with underfill. FIG. 1B is an enlarged photographic image illustrating a crack in a portion A of FIG. 1A.

Referring to FIG. 1A, a conventional semiconductor package includes a substrate 20 and a semiconductor chip 10. External contact terminals (not shown) of the substrate 20 are connected to bonding pads 15 of the semiconductor chip 10 via bumps 30. However, thermal expansion/shrinkage as a result of changes in temperature may occur. Due to a great difference in CTE between the semiconductor chip 10 and the substrate 20 stress may be concentrated on a boundary between the semiconductor chip 10 and the bumps 30. Accordingly, defects may occur.

Product defects, for example, may include cracks caused by a CTE difference. FIG. 1B shows a crack formed in the vicinity of an interfacial surface between the semiconductor chip 10 and one of the bumps 30 in a conventional semiconductor package.

The reliability of the semiconductor package in withstanding thermal expansion/shrinkage is commonly evaluated by a temperature cycle test (T/C test). In this test, the temperature of a device is repeatedly raised and lowered within a range, for example, from about 0° C. to about 125° C. in a period of, for example, 30 minutes, and a defect occurrence cycle is used to determine the reliability of the semiconductor package. The evaluation is continued until a product defect occurs due to a temperature change. A semiconductor package is evaluated as being suitable for commercialization when it exceeds a predetermined number of cycles in the T/C test.

To address this problem, spaces between the bumps 30 are filled and reinforced with an underfill 40. The use of a conventional underfill having a higher Young's modulus (E) may reduce cracks caused by a difference in thermal expansion between a semiconductor chip and a substrate, but may make it difficult to separate the substrate to repair package defects. On the other hand, the use of a conventional underfill having a lower Young's modulus may facilitate the separation of the substrate for repairing package defects, but may increase the amount of cracks. Accordingly, conventional underfill has a trade-off relationship between cracks and reworkability.

### SUMMARY

Example embodiments provide a semiconductor package with heterogeneous underfill which may reduce or prevent cracks formed between a semiconductor chip and conductive bumps and may improve reworkability of the package.

Example embodiments provide a method of manufacturing a semiconductor package with heterogeneous underfill which may reduce or prevent cracks formed between a semiconductor chip and conductive bumps and may improve reworkability of the package.

In an example embodiment, a semiconductor package may include a substrate having external contact terminals. A semiconductor chip having bonding pads may be formed on the substrate. Conductive bumps may connect the external contact terminals of the substrate to the bonding pads of the semiconductor chip. An underfill may be interposed between the substrate and the semiconductor chip. The underfill may include a first underfill region composed of a first material adjacent to the semiconductor chip and a second underfill region composed of a second material adjacent to the substrate. The first material may have a higher glass transition temperature than the second material.

According to an example embodiment, the glass transition temperature of the first material may be about 125° C. to about 250° C.

According to an example embodiment, the glass transition temperature of the second material may be about 0° C. to about 125° C.

According to an example embodiment, the first material may have a higher Young's modulus than the second material.

According to an example embodiment, an interfacial surface between the first underfill region and the second underfill region may be located at a distance from an interfacial surface between the first underfill region and the semiconductor chip corresponding to about 1% to about 99% of the height of the conductive bumps.

According to an example embodiment, an interfacial surface between the first underfill region and the second underfill region may be located at a distance from an interfacial surface between the first underfill region and the semiconductor chip corresponding to about 30% to about 70% of the height of the conductive bumps.

According to an example embodiment, an interfacial surface between the first underfill region and the second underfill region may be located at a distance from an interfacial surface between the first underfill region and the semiconductor chip corresponding to about 45% to about 55% of the height of the conductive bumps.

According to an example embodiment, the first material may include a filler.

According to an example embodiment, the filler may be a metal oxide.

According to an example embodiment, the filler may be one of silica, alumina, titania, zirconia, ceria, and a mixture thereof.

According to an example embodiment, the density of the filler in the first material may increase towards the semiconductor chip.

According to an example embodiment, the first and second materials may include epoxy based resin.

According to an example embodiment, the first and second material may include polymer resin.

In an example embodiment, a method of manufacturing a semiconductor package may include forming conductive bumps on bonding pads of a semiconductor chip; forming a first material on the semiconductor chip around the conductive bumps; bonding the conductive bumps to external contact terminals on a substrate; forming a second material between the material and the substrate. The first material may have a higher glass transition temperature than the second material.

According to an example embodiment, forming a second material between the first material and the substrate may include filling a space between the first material and the substrate with the second material.

According to an example embodiment, filling a space between the first material and the substrate with the second material may include filling the second material by capillary underfilling.

According an example embodiment, forming a second material between the first material and substrate may be performed before bonding the conductive bumps to the external contact terminals of the substrate

According to an example embodiment, forming the second material between the first material and the substrate may include forming a fluid layer including the second material on the substrate, the fluid layer immersing the external contact terminals.

According to an example embodiment, the fluid layer may include a flux.

According to an example embodiment, the height of the first material may be about 1% to about 99% of the height of the conductive bumps.

According to an example embodiment, the height of the first material may be about 30% to about 70% of the height of the conductive bumps.

According to an example embodiment, the height of the first material may be about 45% to about 55% of the height of the conductive bumps.

According to an example embodiment, the method may include curing the first material to form a first underfill region adjacent to the semiconductor chip.

According to an example embodiment, the first material may be cured for about 30 minutes to about 3 hours at a temperature of about 80° C. to about 250° C.

According to an example embodiment, the first material may be fully cured before performing a subsequent process.

According to an example embodiment, the first material may include a filler.

According to an example embodiment, the method may include curing the first material the filler to form a first underfill region adjacent to the semiconductor chip, the filler being sedimented such that the density of the filler increases towards the semiconductor chip.

According to an example embodiment, the method may include curing the second material to form a second underfill region.

According to an example embodiment, the second material may be cured for about 30 minutes to about 10 hours at a temperature of about room temperature to about 250° C.

### BRIEF DESCRIPTION OF THE DRAWINGS

Example embodiments will be described with reference to the accompanying drawings.

FIG. 1A is a cross-sectional view illustrating a conventional semiconductor package with an underfill.

FIG. 1B is an enlarged photograph illustrating a crack formed in a portion A of the semiconductor package of FIG. 1A.

FIG. 2 is a cross-sectional view illustrating a semiconductor package with heterogeneous underfill according to an example embodiment.

FIG. 3 is a graph illustrating a relationship between specific volume of a polymer resin and temperature.

FIG. 4 is a partially enlarged cross-sectional view illustrating a portion B of the semiconductor package of FIG. 2, according to an example embodiment.

FIGS. 5A through 5E are cross-sectional views illustrating a method of manufacturing a semiconductor package with heterogeneous underfill, according to an example embodiment.

FIGS. 6A through 6E are cross-sectional views illustrating a method of manufacturing a semiconductor package with heterogeneous underfill, according to another example embodiment.

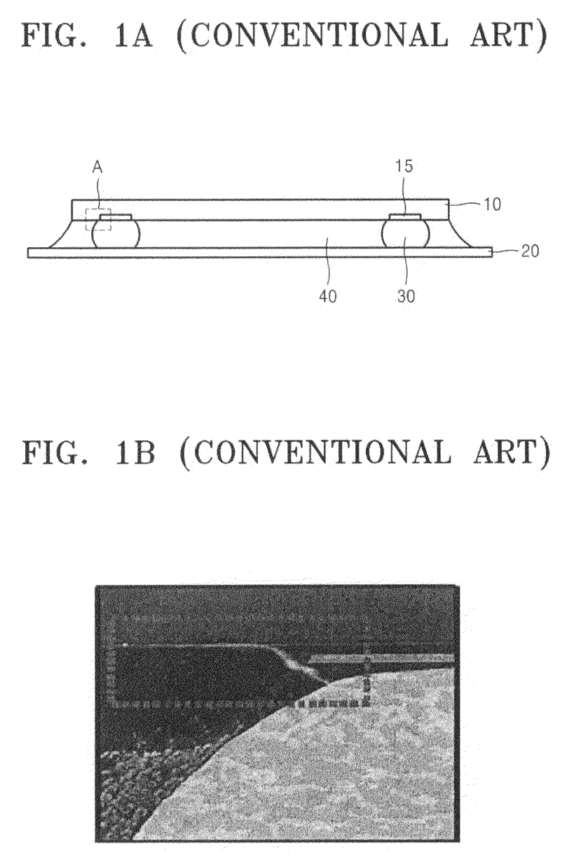

### DESCRIPTION OF EXAMPLE EMBODIMENTS

Example embodiments will now be described with reference to the accompanying drawings. Example embodiments may, however, be embodied in many different forms and should not be construed as being limited to the example embodiments set forth herein. Rather, these example embodiments are provided so that this disclosure will be thorough, and will fully convey the scope to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to example embodiments, a semiconductor package may be formed having a heterogeneous underfill in which product defects caused by cracks may be reduced or prevented despite a coefficient of thermal expansion (CTE) difference between a semiconductor chip and a substrate. According to example embodiments, the semiconductor chip may be more easily separated from the substrate, thereby significantly enhancing reworkability for repairing.

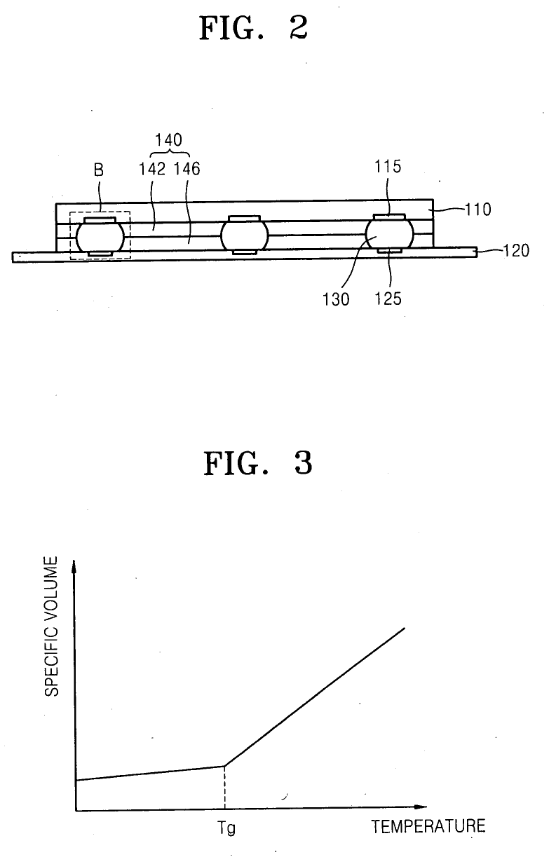

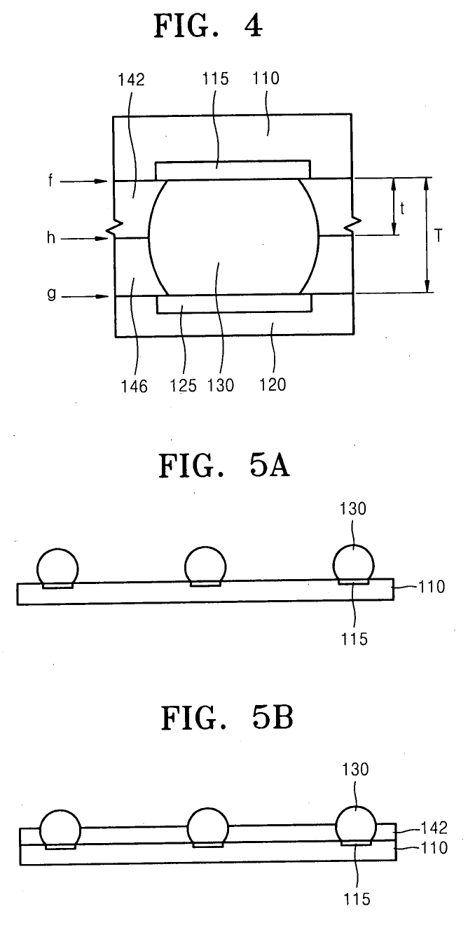

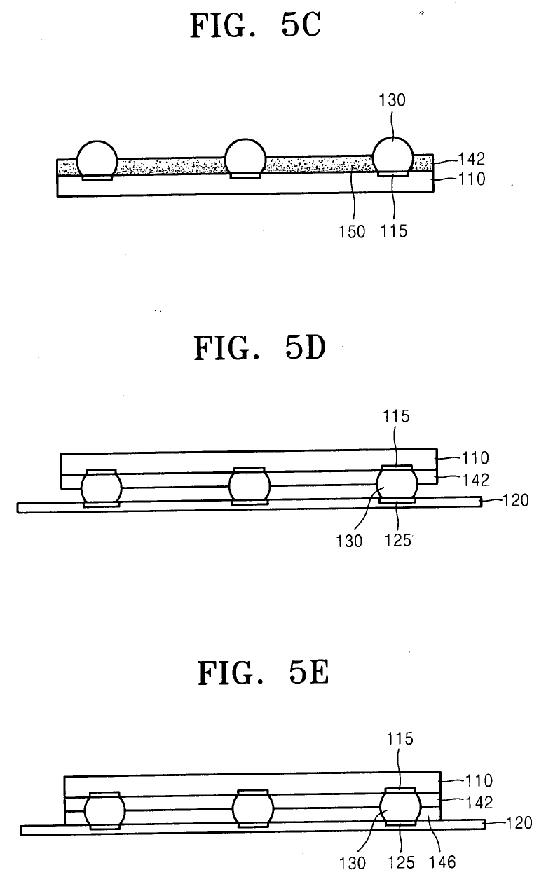

FIG. 2 is a cross-sectional view illustrating a semiconductor package according to an example embodiment. FIG. 3 is a graph illustrating a general change of a specific volume of a polymer resin according to temperature change. FIG. 4 is an enlarged cross-sectional view illustrating a portion B of the semiconductor package of FIG. 2, according to an example embodiment.

Referring to FIG. 2, a semiconductor package, according an example embodiment, may include a substrate 120 having external contact terminals 125; a semiconductor chip 110 having bonding pads 115 and disposed on the substrate 120; conductive bumps 130 connecting the external contact terminals 125 of the substrate 120 to the bonding pads 115 of the semiconductor chip 110; and an underfill 140 interposed between the substrate 120 and the semiconductor chip 110.

The underfill 140 may be a heterogeneous underfill including a plurality of underfill regions having different physical properties and that are stacked on each other. The heterogeneous underfill may include polymer resins, for example, epoxy based resins. However, epoxy based resins may vary widely in physical properties, for example, glass transition temperature, Young's modulus, and the like, depending on molecular weight distribution, number-average molecular weight, weight-average molecular weight, polydispersity index, etc. Accordingly, the heterogeneous underfill may include a stack of two different polymer resins having different physical properties or a stack of two epoxy based resins having different properties.

According to an example embodiment as shown in FIG. 2, the underfill 140 may include a first underfill region 142 adjacent to the semiconductor chip 110 and a second underfill region 146 adjacent to the substrate 120. A first material composing the first underfill region 142 may have a higher glass transition temperature than a second material composing the second underfill region 146. The first material may have a glass transition temperature of about 125° C. to 250° C., for example, about 130° C. to 200° C., or about 135° C. to 180° C. Further, the second material may have a glass transition temperature of about 0° C. to 125° C., for example, about 40° C. to 120° C., or about 60° C. to 115° C.

A polymer resin having a relatively higher glass transition temperature may have a higher Young's modulus than a polymer resin having a relatively lower glass transition temperature. Accordingly, the first underfill region 142 may have a higher Young's modulus than the second underfill region 146. However, the value of the Young's modulus is not limited to a specific range.

Because the first underfill region 142 has a higher Young's modulus than that of the second underfill region 146, the stress, which was conventionally concentrated on the interfacial surface between the semiconductor chip 110 and conductive bumps 130, may be partially transferred to regions of the conductive bumps in the vicinity of the interfacial surface between the first underfill region 142 and the second underfill region 146. Thus, cracks may be reduced or prevented from occurring in an interfacial surface between the conductive bumps 130 and the semiconductor chip 110. Further, because the Young's modulus of the second underfill region 146 is lower than that of the first underfill region 142, the second material composing the second underfill region 146 may be more easily separated from the substrate 120, thereby improving reworkability of the semiconductor package.

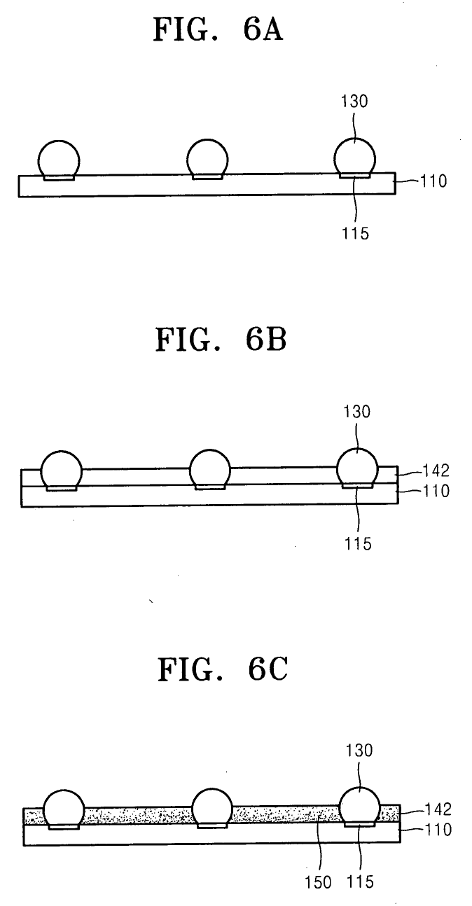

The first underfill region 142 may include a filler 150 (shown in FIG. 5C) to improve the Young's modulus of the first underfill region 142. Therefore, more filler 150 may be distributed in a portion of the first underfill region 142 at the side of the semiconductor chip 110 requiring a higher Young's modulus, for example, the filler in the first underfill region 142 may have a density that increases towards the semiconductor chip 110. The filler 150 may be a metal oxide, for example, silica (SiO₂), alumina (Al₂O₃), titania (TiO₂), zirconia (ZrO₂), ceria (CeO₂), etc. or a mixture thereof.

Referring to FIG. 3, a specific volume of a polymer resin has a correlation with CTE. The specific volume of a polymer resin may increase in proportion to temperature, as is well known in the art. For example, the specific volume may increase sharply at a temperature higher than a glass transition temperature T_{g}. If the glass transition temperature is sufficiently high, the polymer resin may not undergo sudden linear thermal expansion and thermal shrinkage, which may be involved at a higher temperature than the glass transition temperature. Thus, a stress induced by a temperature change may be lower even if the polymer resin is attached to a material having a lower coefficient of thermal expansion. If the glass transition temperature is lower, the polymer resin may undergo sudden linear thermal expansion and thermal shrinkage at a higher temperature than the glass transition temperature. Thus, a stress induced by a temperature change may be lower even if the polymer resin is attached to a material having a higher coefficient of thermal expansion.

Referring to FIG. 4, the semiconductor chip 110 may have a smaller CTE and the substrate 120 may have a greater CTE. Accordingly, if a first material having a higher glass transition temperature is formed in the first underfill region 142 and is attached to the semiconductor chip 110, stress applied by a temperature change to an interfacial surface f between the first underfill region 142 and the semiconductor chip 110 may be reduced. Further, if a second material having a lower glass transition temperature is formed in the second underfill region 146 and attached to the substrate 120, stress applied by a temperature change to an interfacial surface g between the second underfill region 146 and the semiconductor chip 110 may be reduced. Meanwhile, stress may be generated by a temperature change on an interfacial surface h between the first underfill region 142 and the second underfill region 146 at which the first material and the second material are bonded to each other, but the stress may not be high enough to cause a crack in the conductive bump 130. Accordingly, the stress on the interfacial surface h may be unlikely to cause device defects.

A proper ratio may be maintained between height of the first underfill region 142 and the second underfill region 146. The interfacial surface h between the first underfill region 142 and the second underfill region 146 may be positioned at a distance t from the interfacial surface between contacts 115 of the semiconductor chip 110 and the conductive bump 130. The distance t may correspond to about 1% to 99% of a height T of the conductive bump 130, for example, about 30% to 70%, or about 45% to 55%.

If the position of the interfacial surface h between the first underfill region 142 and the second underfill region 146 is outside this range, enough of the stress may not be transferred to the center of the conductive bumps 130 and the amount of cracks in the interfacial surfaces f and g may not be reduced.

FIGS. 5A through 5E are cross-sectional views illustrating a method of manufacturing a semiconductor package with heterogeneous underfill according to an example embodiment.

Referring to FIG. 5A, a method of manufacturing a semiconductor package may include forming conductive bumps 130 on contacts 115 of a semiconductor chip 110. The conductive bumps 130 may be formed using a conventional method, but example embodiments are not limited thereto.

Referring to FIG. 5B, a first material may be formed on the semiconductor chip 110 between the conductive bumps 130 and cured to form a first underfill region 142. The first underfill region 142 may be formed, for example, by screen-printing the first material on the semiconductor chip 110, but example embodiments are not limited thereto. The first material may be dried for about 30 minutes to about 3 hours at a temperature of about 80° C. to about 250° C. to be cured. As a result, the formation of the first underfill region 142 may be complete. In this case, the first material may be fully cured, but may not be half-cured.

Referring to FIG. 5C, in an example embodiment, the first material may include a filler 150. The filler 150 may be a metal oxide, for example, silica (SiO₂), alumina (Al₂O₃), titania (TiO₂), zirconia (ZrO₂), ceria (CeO₂), etc. or a mixture thereof. Because the first material is cured as the filler 150 is sedimented, the density of the filler 150 may increase toward the semiconductor chip 110. The density distribution of the filler 150 may be selected by adjusting the viscosity of the first material, and the specific gravity, shape, size, etc. of the filler 150.

Referring to FIG. 5D, the resulting structure may be turned over and disposed on a substrate 120 having external contact terminals 125. The resulting structure may be selectively pressed, and heat may be applied to the conductive bumps 130 to bond the conductive bumps 130 to the external contact terminals 125 of the substrate 120, thus bonding the resulting structure to the substrate 120. A space may be formed between the first underfill region 142 and the substrate 120.

Referring to FIG. 5E, a second material may be filled in the space between the first underfill region 142 and the substrate 120, and the second material may be cured to form a second underfill region 146. The second material may be filled, for example, by capillary underfilling, but example embodiments are not limited thereto and other methods may be used. The second material filled may be dried for about 30 minutes to about 10 hours at a temperature of about room temperature to about 250° C. to be cured.

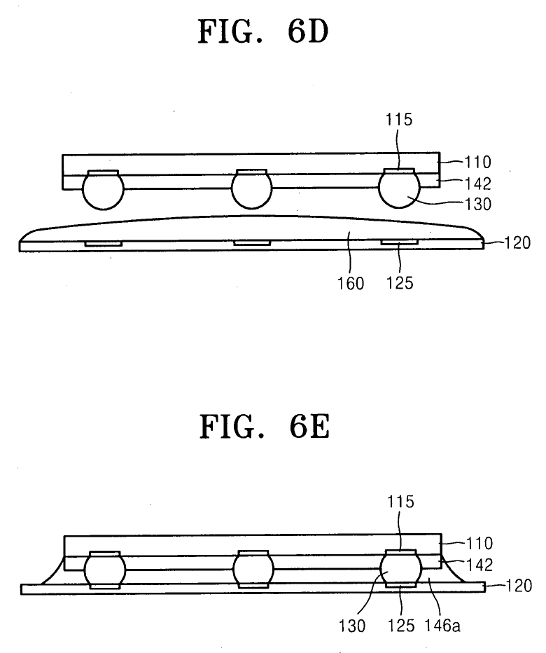

FIGS. 6A through 6E are cross-sectional views sequentially illustrating a method of manufacturing a semiconductor package with heterogeneous underfill according to another example embodiment.

FIGS. 6A to 6C illustrate a method the same as FIGS. 5A to 5C, and thus a description thereof will be omitted.

Referring to FIG. 6D, a fluid layer 160 including a second material may be formed on the substrate 120 having external contact terminals 125. The external contact terminals 125 may be fully immersed in the fluid layer 160. For example, a temperature of the fluid layer 160 may be adjusted so that the second material has a suitable viscosity. The viscosity of the fluid layer 160 may be sufficiently low so that the conductive bumps 130 may pass through the fluid layer 160 without much difficulty and so that a space between the first underfill region 142 and the substrate 120 may be filled with the fluid layer 160 without requiring other processes. However, the viscosity must be sufficiently high so that the fluid layer 160 may remain on the substrate 120 with proper surface tension during the process.

The fluid layer 160 may include a flux to allow the conductive bumps 130 and the external contact terminals 125 to be bonded to each other without much difficulty.

In FIG. 6E, the conductive bumps 130 may be bonded to the external contact terminals 125 of the substrate 120, and the fluid layer 160 interposed between the first underfill region 142 and the substrate 120 may be cured to form a second underfill region 146a.

Because the fluid layer 160 in FIG. 6D fills the space between the first underfill region 142 and the substrate 120 and has suitable viscosity to fill the space without requiring other processes, the fluid layer 160 may fill the space between the first underfill region 142 and the substrate 120 by itself. The second material of the fluid layer 160 may also be formed along an outer side surface of the semiconductor package as illustrated in FIG. 6E.

According to example embodiments, a semiconductor package with heterogeneous underfill may concentrate the majority of stress at an interfacial surface between a semiconductor chip and conductive bumps, bonding the semiconductor chip to a substrate, toward a center of the conductive bumps; thereby reducing or preventing cracks from occurring between the semiconductor chip and the conductive bumps and facilitating the reworkability of the package.

While example embodiments have been particularly shown and described, it will be understood by those of ordinary skill in the art that various changes in form and details may be made therein without departing from the spirit and scope of the present invention.

What is claimed is:

1. A semiconductor package, comprising:
a substrate having external contact terminals;
a semiconductor chip having bonding pads formed on the substrate;
conductive bumps connecting the external contact terminals of the substrate to the bonding pads of the semiconductor chip; and
an underfill interposed between the substrate and the semiconductor chip, wherein the underfill includes a first underfill region composed of a first material adjacent to the semiconductor chip and a second underfill region composed of a second material adjacent to the substrate, the first material having a higher glass transition temperature than the second material.

2. The semiconductor package of claim 1, wherein the glass transition temperature of the first material is about 125° C. to about 250° C.

3. The semiconductor package of claim 1, wherein the glass transition temperature of the second material is about 0° C. to about 125° C.

4. The semiconductor package of claim 1, wherein the first material has a higher Young's modulus than the second material.

5. The semiconductor package of claim 1, wherein an interfacial surface between the first underfill region and the second underfill region is located at a distance from an interfacial surface between the first underfill region and the semiconductor chip corresponding to about 1% to about 99% of the height of the conductive bumps.

6. The semiconductor package of claim 1, wherein an interfacial surface between the first underfill region and the second underfill region is located at a distance from an interfacial surface between the first underfill region and the semiconductor chip corresponding to about 30% to about 70% of the height of the conductive bumps.

7. The semiconductor package of claim 1, wherein an interfacial surface between the first underfill region and the second underfill region is located at a distance from an interfacial surface between the first underfill region and the semiconductor chip corresponding to about 45% to about 55% of the height of the conductive bumps.

8. The semiconductor package of claim 1, wherein the first material includes a filler.

9. The semiconductor package of claim 8, wherein the filler is a metal oxide.

10. The semiconductor package of claim 9, wherein the filler is one of silica, alumina, titania, zirconia, ceria, and a mixture thereof.

11. The semiconductor package of claim 10, wherein the density of the filler in the first material increases towards the semiconductor chip.

12. The semiconductor package of claim 1, wherein the first and second materials include epoxy based resin.

13. The semiconductor package of claim 1, wherein the first and second materials include polymer resin.

14. A method of manufacturing a semiconductor package, the method comprising:
forming conductive bumps on bonding pads of a semiconductor chip;
forming a first material on the semiconductor chip around the conductive bumps;
bonding the conductive bumps to external contact terminals on a substrate; and
forming a second material between the first material and the substrate, the first material having a higher glass transition temperature than the second material

15. The method of claim 14, wherein forming a second material between the first material and the substrate includes filling a space between the first material and the substrate with the second material.

16. The method of claim 15, wherein filling a space between the first material and the substrate with the second material includes filling the space with the second material by capillary underfilling.

17. The method of claim 14, wherein forming a second material between the first material and substrate is performed before bonding the conductive bumps to the external contact terminals of the substrate.

18. The method of claim 17, wherein forming the second material between the first material and the substrate includes forming a fluid layer including the second material on the substrate, the fluid layer immersing the external contact terminals.

19. The method of claim 18, wherein the fluid layer includes a flux.

20. The method of claim 14, wherein the height of the first material is about 1% to about 99% of the height of the conductive bumps.

21. The method of claim 14, wherein the height of the first material is about 30% to about 70% of the height of the conductive bumps.

22. The method of claim 14, wherein the height of the first material is about 45% to about 55% of the height of the conductive bumps.

23. The method of claim 14, further comprising curing the first material to form a first underfill region adjacent to the semiconductor chip.

24. The method of claim 23, wherein the first material is cured for about 30 minutes to about 3 hours at a temperature of about 80° C. to about 250° C.

25. The method of claim 23, wherein the first material is fully cured before performing a subsequent process.

26. The method of claim 14, wherein the first material includes a filler.

27. The method of claim 26, further comprising curing the first material to form a first underfill region adjacent to the semiconductor chip, the filler being sedimented such that the density of the filler increases towards the semiconductor chip.

28. The method of claim 14, further comprising curing the second material to form a second underfill region.

29. The method of claim 28, wherein the second material is cured for about 30 minutes to about 10 hours at a temperature of about room temperature to about 250° C.
